(19) United States
(12) Patent Application Publication
(10) Pub. No.: US 2026/0206431 A1
(43) Pub. Date: Jul. 16, 2026

(54) DISPLAY DEVICE INCLUDING BLOCKING LAYER, ELECTRONIC DEVICE INCLUDING THE DISPLAY DEVICE, AND METHOD OF MANUFACTURING THE DISPLAY DEVICE

(71) Applicant: SAMSUNG DISPLAY CO., LTD., YONGIN-SI (KR)

(72) Inventors: Seung Bae KANG, Yongin-si (KR); Young Rok KIM, Yongin-si (KR); Woo Jin CHO, Yongin-si (KR)

(21) Appl. No.: 19/445,862

(22) Filed: Jan. 12, 2026

(30) Foreign Application Priority Data
Jan. 16, 2025 (KR) 10-2025-0006823

(51) Int. Cl. H10K 59/126; H10K 59/12; H10K 59/121; H10K 59/122; H10K 59/80; H10K 71/60; H10K 102/10

(52) U.S. Cl. CPC H10K 59/126; H10K 59/1201; H10K 59/1213; H10K 59/122; H10K 59/80517; H10K 71/60; H10K 2102/101

(57) ABSTRACT

A display device including a base substrate, pixel electrodes spaced apart from each other and disposed on the base substrate, a blocking layer disposed between the pixel electrodes, a light-emitting portion disposed on the pixel electrodes, and a counter electrode disposed on the light-emitting portion. The upper surface of the blocking layer is coplanar with upper surfaces of the pixel electrodes.

### CROSS-REFERENCE TO RELATED APPLICATION

This U.S. non-provisional patent application claims priority under 35 U.S.C. §119 to Korean Patent Application No. 10-2025-0006823 filed on January 16, 2025, in the Korean Intellectual Property Office (KIPO), the entire disclosure of which is incorporated by reference herein.

### TECHNICAL FIELD

Embodiments of the present disclosure relate to a display device and more particularly to, a display device including a blocking layer, an electronic device including the display device, and a method of manufacturing the display device.

### DISCUSSION OF THE RELATED ART

In a display device, such as an organic light emitting diode (OLED) display device and a liquid crystal display (LCD) device, a display substrate may include components such as a thin film transistor (TFT) and various wirings. The display structure may include electrodes and emission layers formed on the display substrate.

For example, electrodes may connect the TFT and the display structure. Recently, various configurations of the TFT and the electrodes have been researched to enable a high-resolution display device.

### SUMMARY

A display device includes a base substrate, pixel electrodes spaced apart from each other and disposed on the base substrate, a blocking layer arranged between the pixel electrodes. The upper surface of the blocking layer is coplanar with upper surfaces of the pixel electrodes. The display device further includes a light-emitting portion disposed on the pixel electrodes, and a counter electrode disposed on the light-emitting portion.

In some embodiments, the blocking layer may surround side surfaces of the pixel electrodes.

In some embodiments, the display device may further include a pixel defining layer covering the upper surface of the blocking layer to form pixel areas on the pixel electrodes.

In some embodiments, the pixel defining layer may completely cover the upper surface of the blocking layer and at least a portion of the upper surfaces of the pixel electrodes.

In some embodiments, the blocking layer may include a hole into which each of the pixel electrodes is inserted, and the pixel defining layer may include an opening overlapping the hole and exposing an upper surface of each of the pixel electrodes. An area of the hole may be larger than an area of the opening in a plan view.

In some embodiments, the blocking layer may include an organic polymer material.

In some embodiments, the pixel electrodes may include a first transparent conductive oxide layer, a metal layer, and a second transparent conductive oxide layer sequentially stacked.

In some embodiments, the metal layer may include silver (Ag).

In some embodiments, the display device may further include transistor structures disposed on the base substrate and electrically connected to each of the pixel electrodes, and a peripheral circuit and pads electrically connected to the transistor structure. The base substrate may have a display area including the transistor structures, and a non-display area surrounding the display area. The non-display area may include the peripheral circuit and the pads.

In some embodiments, the blocking layer exposes the peripheral circuit and/or the pads.

In some embodiments, the blocking layer may be disposed only on the display area.

In a method for manufacturing a display device, a via insulation layer may be formed on a base substrate. A pixel electrode layer may be formed on the via insulation layer. Photoresist patterns may be formed on the pixel electrode layer. The pixel electrode layer may be etched sing the photoresist patterns to form pixel electrodes. A blocking coating layer covering the photoresist patterns and the pixel electrodes may be formed. Upper portions of the blocking coating layer and the photoresist patterns may be removed to form a blocking layer between the pixel electrodes. A light-emitting portion may be formed on the pixel electrodes. A counter electrode may be formed on the light-emitting portion.

In some embodiments, removing the upper portions of the blocking coating layer and the photoresist patterns may include performing an ashing process.

In some embodiments, in the formation of the pixel electrode layer, a first transparent conductive oxide layer, a metal layer including silver (Ag), and a second transparent conductive oxide layer may be sequentially formed on the via insulation layer. The second transparent conductive oxide layer may be an ashing stopper layer during the ashing process.

In some embodiments, removing the upper portions of the blocking coating layer and the photoresist patterns may include performing a chemical mechanical polishing (CMP) process.

In some embodiments, in the formation of the pixel electrode layer, a first transparent conductive oxide layer, a metal layer including silver (Ag), and a second transparent conductive oxide layer may be sequentially formed on the via insulation layer. The second transparent conductive oxide layer may be a polishing stopper layer during the CMP process.

In some embodiments, a side portion of the blocking coating layer may be removed.

In some embodiments, the blocking coating layer may be formed using a photosensitive organic polymer.

An electronic device may include a display device, a memory having a stored application for operating the electronic device including the display device, and a processor configured to execute the application stored in the memory. The display device may include a base substrate, pixel electrodes spaced apart from each other and disposed on the base substrate, a blocking layer disposed between the pixel electrodes, where an upper surface of the blocking layer is coplanar with upper surfaces of the pixel electrodes, a light-emitting portion disposed on the pixel electrodes, and a counter electrode disposed on the light-emitting portion.

In some embodiments, the electronic device may include virtual reality glasses, augmented reality glasses, a smartphone, a tablet PC, a laptop, a TV, a desk monitor, smart glasses, a head-mounted display, a smart watch, or a vehicle display.

In a display device according to some embodiments of the present inventive concepts, a pixel electrode may have a stacked structure of a transparent conductive oxide layer and a metal layer, and the display device may include a blocking layer between the pixel electrodes. Damages and oxidation of the metal layer may be prevented by the blocking layer, and hole injection and electrical conduction properties through the pixel electrode may be improved.

### BRIEF DESCRIPTION OF THE DRAWINGS

FIG. 1 is a schematic plan view illustrating a display device according to some embodiments.

FIG. 2 is a pixel circuit diagram of a display device according to some embodiments.

FIG. 3 is a schematic plan view illustrating a display area of a display device according to some embodiments.

FIG. 4 is a cross-sectional view illustrating a display device according to some embodiments.

FIG. 5 is a schematic cross-sectional view illustrating a peripheral area or a pad area of a display device according to some embodiments.

FIGS. 6 and 7 are schematic cross-sectional views illustrating a light-emitting device according to some embodiments.

FIG. 8 is a partially enlarged cross-sectional view of a display device according to some embodiments.

FIGS. 9, 10, 11, 12, 13, 14 and 15 are schematic cross-sectional views illustrating a method of manufacturing a display device according to some embodiments.

FIG. 16 is an exploded perspective view of a display device according to some embodiments.

FIG. 17 is a block diagram of an electronic device according to an embodiment.

FIG. 18 is a schematic diagram of electronic devices according to some embodiments.

### DETAILED DESCRIPTION OF THE EMBODIMENTS

Hereinafter, embodiments of the present invention are described in detail with reference to the attached drawings. The same reference numerals may be used to indicate the same elements disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The terms "on", "connected", "coupled," etc., used herein refers to a relative placement between elements. For example, a layer, region, or element is referred to as being formed on another layer, region, or element, the layer, region, or element can be directly or indirectly formed on the other layer, region, or element. For example, intervening layers, regions, or elements may be present between the layers, regions, or elements, respectively. As used herein, the term “top surface” may also be referred to as “upper surface”.

The terms such as "first", "second", "below", "under", "above," "on," etc., are used in a relative sense to distinguish different elements or positions, and do not specify an absolute position or an absolute order. These terms are used to distinguish one element from another element. For example, a first element discussed below could be termed a second element without departing from the teachings of the present invention. Similarly, the second element could also be termed the first element.

Embodiments of the present disclosure provide a display device including a plurality of pixel electrodes disposed on a base substrate. A blocking layer may be formed between adjacent pixel electrodes such that a top surface of the blocking layer may be coplanar with top surfaces of the pixel electrodes. The pixel electrodes may include a stacked structure including a first transparent conductive oxide layer, a metal layer including silver (Ag), and a second transparent conductive oxide layer. By forming the blocking layer to surround the side surfaces of the pixel electrodes and aligning the top surface with the top surface of the electrodes, embodiments of the present disclosure may improve layer uniformity and protect the underlying metal layer from oxidation or damage during dry etching or ashing processes.

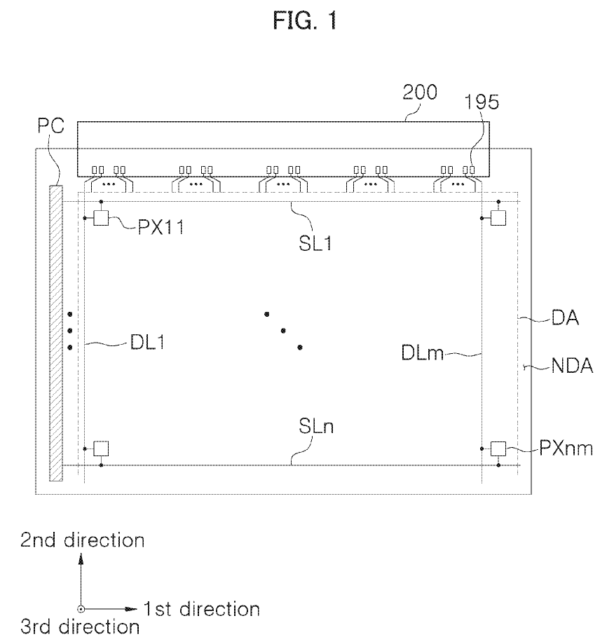

FIG. 1 is a schematic plan view illustrating a display device according to some embodiments.

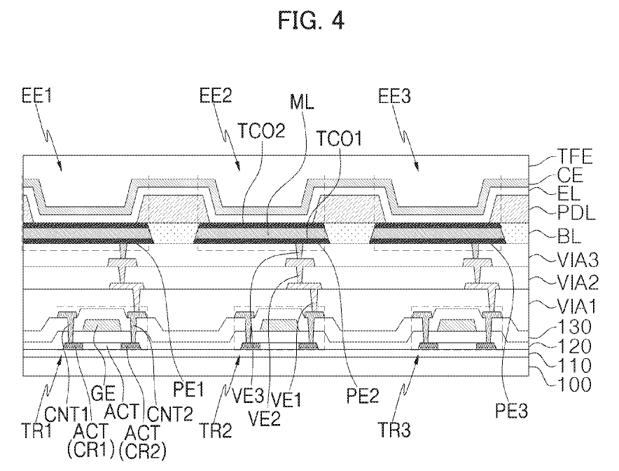

In FIG. 1, a first direction and a second direction may refer to two directions parallel to a top surface of a base substrate 100 (see FIG. 4) and intersecting (e.g., crossing or perpendicular to) each other. For example, the first direction and the second direction may be orthogonal to each other.

For example, the first direction may correspond to an X-direction (e.g., a row direction or a width direction) of the display device, and the second direction may correspond to a Y-direction (e.g., a column direction or a length direction) of the display device.

The third direction may be perpendicular to the first direction and the second direction. The third direction may correspond to a Z-direction (a thickness direction) of the display device.

In the accompanying drawings, the above description of the directions may be equally applied, and are used to describe the relative arrangement of circuit elements, electrode structures, and layers formed on the base substrate.

Referring to FIG. 1, the display device may include a display area DA and a non-display area NDA. The display area DA may may define a region in which an image is actively displayed and touch input may be received. The non-display area NDA may substantially correspond to a bezel area or a peripheral region of the display device. In an embodiment, the display area DA may be substantially surrounded by the non-display area NDA. In some cases, the non-display area NDA may accommodate components such as driver circuits, pads, or interconnects.

The base substrate 100 may also be divided into the display area DA and the non-display area NDA. A plurality of pixels PX11 to PXnm may be arranged on the display area DA of the base substrate 100 in a matrix form corresponding to intersections of scan lines and data lines.

In an embodiment, a pixel circuit including scan lines SL1 to SLn (or gate lines) forming first to n^{th} rows, and data lines DL1 to DLm forming first to m^{th} columns may be arranged on the base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm. In some cases, each of n and m is an integer greater than or equal to 1.

Each of the pixels PX11 to PXnm may further include a pixel circuit including a transistor and a light-emitting device. In some embodiments, the pixel circuit may further include wirings such as additional wiring lines including a power line, a ground line, or other signal lines.

FIG. 1 illustrates that the data lines DL1 to DLm extend in the second direction and the scan lines SL1 to SLn extend in the first direction, but the construction of the data lines and the gate lines is not necessarily limited to that illustrated in FIG. 1. In some embodiments, the orientation of the data lines and scan lines may be reversed or configured in a zigzag or non-orthogonal pattern based on the display architecture. In FIG. 1, each pixel PX11 to PXnm is illustrated as a square shape for illustrative convenience, but the shape of each pixel is not necessarily limited to the example illustrated in FIG. 1. For example, a pixel may have a rectangular, diamond, hexagonal, or irregular shape based on sub-pixel arrangement.

A peripheral circuit PC may be disposed in the non-display area NDA corresponding to a peripheral area PA of the display area DA. For example, the peripheral circuit PC may include a gate driving circuit. The gate driving circuit may be formed on the same substrate as the display panel DP using an oxide semiconductor gate (OSG) driver circuit process, an amorphous silicon gate (OSG) driver circuit process, or a polysilicon gate (PSG) driver circuit process.

The peripheral circuit PC may further include a data driver, a gate driver, a light-emitting driver, a power voltage generator, a timing controller, or other functional components.

The display device may further include a printed circuit board 200. Pads 195 electrically connected to the pixel circuit may be disposed at one end portion of the non-display area NDA. The printed circuit board 200 may be electrically connected to the pixel circuit through the pads 195. For example, the printed circuit board 200 may be electrically connected to the pads 195 by a heat-compression process using a conductive intermediate structure such as an anisotropic conductive film ACF.

An integrated circuit (IC), such as a data driving circuit, may be disposed on the printed circuit board 200. In some embodiments, an integrated circuit (IC) chip in the form of a chip-on-film (COF) may be mounted on the printed circuit board 200. In some embodiments, a chip-on-glass (COG) structure may be used, where the IC is bonded to the substrate (e.g., a glass substrate).

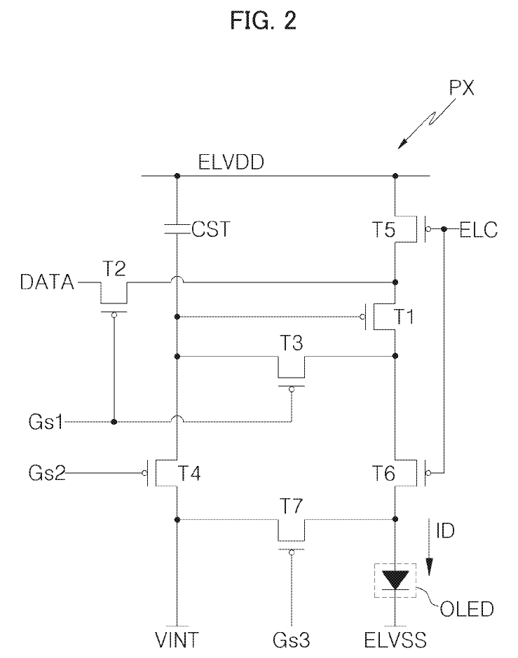

FIG. 2 is a pixel equivalent circuit diagram of a display device according to some embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may serve as a driving transistor for supplying current to an organic light-emitting diode (OLED) element.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second terminal may be connected to the first terminal of the first transistor T1 to supply the data voltage DATA. For example, the second transistor T2 may serve as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may be configured to initialize the gate terminal of the first transistor T1.

The fifth transistor T5 may include a gate terminal, a first terminal and a second terminal. The gate terminal may receive an emission control signal ELC. The first terminal may receive a supply voltage ELVDD. The second terminal may be connected to the first transistor T1. The fifth transistor T5 may control the power (or voltage) of the supply voltage ELVDD to the drive transistor in synchronization with emission timing.

The sixth transistor T6 may include a gate terminal, a first terminal and a second terminal. The gate terminal may receive the emission control signal ELC. The first terminal may be connected to the second terminal of the first transistor T1. The second terminal may be connected to an organic light emitting diode OLED. The sixth transistor T6 may transfer the driving current ID to the organic light emitting diode OLED in response to the emission control signal ELC.

The seventh transistor T7 may include a gate terminal, a first terminal and a second terminal. The gate terminal may receive a third gate signal Gs3. The first terminal may be connected to the organic light emitting diode OLED. The second terminal may receive the initialization voltage VINT. The seventh transistor T7 may be configured to initialize the organic light emitting diode OLED. For example, the seventh transistor T7 may reset the organic light emitting diode OLED to a known voltage (e.g., initialization voltage VINT) during initialization.

The storage capacitor CST may include a first terminal and a second terminal. The first terminal may receive the high-power supply voltage ELVDD. The second terminal may be connected to the gate terminal of the first transistor T1. The storage capacitor CST may store a gate-driving voltage for maintaining a current level during emission

The organic light-emitting diode OLED may include a first terminal and a second terminal. The first terminal may be connected to the sixth transistor T6. The second terminal may receive a low-power supply voltage ELVSS. The organic light emitting diode OLED may emit light based on the magnitude of the driving current ID supplied from the driving transistor T1.

In FIG. 2, a 7T1C circuit configuration is illustrated, including seven thin film transistors and one storage capacitor CST in each pixel PX. However, the pixel structure of the display device is not necessarily limited thereto.

For example, each pixel PX may include two or more transistors, and may have a circuit configuration such as 2T1C, 5T1C, 6T1C, 5T2C, 6T2C, or other variations.

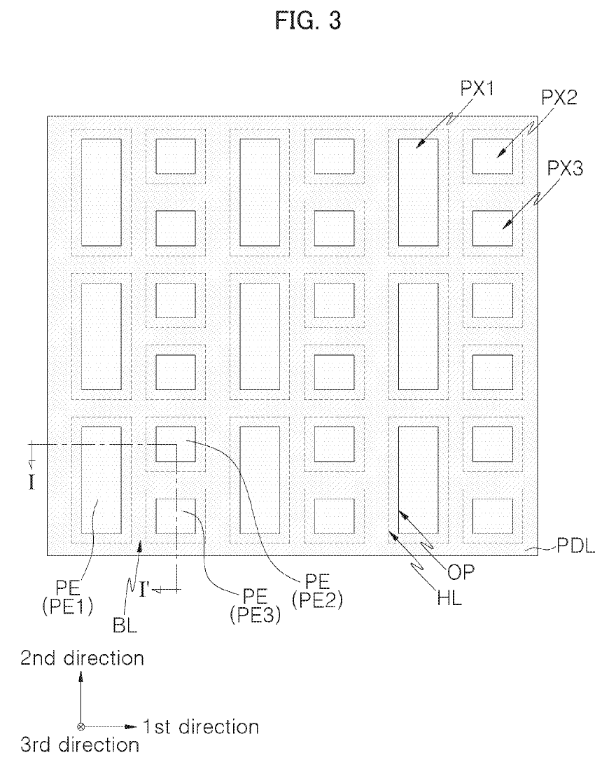

FIG. 3 is a schematic plan view illustrating a display area of a display device according to some embodiments. FIG. 4 is a cross-sectional view illustrating a display device according to some embodiments. For example, FIG. 4 is a cross-sectional view taken along line a I-I' of FIG. 3 in a thickness direction (e.g., the third direction).

Referring to FIGS. 3 and 4, a display device may include a base substrate 100, a pixel circuit including transistor structures TR1, TR2, and TR3, and a light-emitting element EE.

The base substrate 100 may serve as a backplane substrate of the display device. A glass substrate, a ceramic substrate, or a plastic substrate may be used as the base substrate 100. In some cases, a polymer may be used as the base substrate 100. In some embodiments, the base substrate 100 may include a polymer material having transparency and flexibility. For example, the base substrate 100 may be used in a transparent flexible display device.

For example, the base substrate 100 may include a polymer material such as polyimide, polysiloxane, an epoxy resin, an acrylic resin, polyester, or other polymer materials. In an embodiment, the base substrate 100 may include polyimide for enhanced mechanical and thermal stability.

In some embodiments, the base substrate 100 may be a silicon substrate obtained from a silicon wafer.

A buffer layer 110 may be formed on a top surface of the base substrate 100. The buffer layer 110 may prevent moisture ingress and suppress impurity diffusion from the base substrate 100 into other active layers. The buffer layer 110 may be formed entirely over the display area DA and the non-display area NDA of the base substrate 100, and may substantially cover the top surface of the base substrate 100.

The buffer layer 110 may include, for example, an inorganic insulating material such as silicon oxide (SiOₓ), silicon nitride (SiNₓ), silicon oxynitride (SiₓN_{y}), or a combination thereof.

In some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or other deposition processes, to include the above-mentioned inorganic insulating material.

In some embodiments, the buffer layer 110 may include an organic layer, and may have a multi-layered structure including an organic layer and an inorganic layer. In some cases, the inclusion of an organic-inorganic stacked structure may enhance mechanical flexibility and/or barrier performance.

The pixel circuit may include wirings such as the scan lines and the data lines described with reference to FIG. 1, and transistor structures TR1, TR2, and TR3 electrically interacting with the wires. Each of the transistor structures TR1, TR2, and TR3 may be electrically connected to a corresponding light-emitting elements EE1, EE2, and EE3, respectively.

The transistor structures TR1, TR2, and TR3 may include an active layer ACT, a gate insulation layer 120, and a gate electrode GE. Each of the transistor structures TR1, TR2, and TR3 may further include contact electrodes CNT1 and CNT2 for electrical interfacing with external circuit components.

The active layer ACT may be disposed on the buffer layer 110, and may be patterned through a photo-lithography process to form repetitive transistor structures at each pixel. The active layer ACT may include a silicon-based semiconductor material such as polysilicon or amorphous silicon. A p-type dopant or an n-type dopant may be doped in a partial region of the active layer ACT, and the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on an active layer ACT, and a gate electrode GE may be stacked on the gate insulation layer 120. As illustrated in FIG. 4, the gate insulation layer 120 may be commonly formed over the first, second, and third transistor structures TR1, TR2, and TR3 or over multiple pixels having different emission colors.

In an embodiment, the gate insulation layer 120 may partially cover each active layer ACT, and may be formed into an individual patterned structure for each of the first, second, and third transistor structures TR1, TR2, and TR3.

The gate electrode GE may overlap the channel region of the active layer ACT in the third direction. A scan signal may be transmitted from the scan line and applied to the gate electrode GE via a corresponding scan line.

The gate insulation layer 120 may be formed by the above-mentioned deposition process to include an inorganic insulating material such as silicon oxide (SiOx), silicon nitride (SiNx), silicon oxynitride (SiON), or a metal oxide.

In some embodiments, a p-type dopant or an n-type dopant may be injected into the active layer ACT by an ion implantation process using the gate electrode GE as an ion implantation mask. Accordingly, a first contact region CR1 and a second contact region CR2 may be formed on opposite sides of the active layer ACT. The first contact region CR1 may serve as a source region, and the second contact region CR2 may serve as a drain region.

A portion of the active layer ACT overlapping the gate electrode GE in a vertical direction (e.g., the third direction) and disposed between the first contact region CR1 and the second contact region CR2 may represent the channel region.

In some embodiments, the gate insulation layer 120 may be formed in a patterned shape covering the channel region through an etching process using the gate electrode GE as an etching mask. When the active layer ACT includes the oxide semiconductor, hydrogen (H) included in an insulating interlayer 130 may diffuse into the active layer ACT during the formation of the insulating interlayer 130. Accordingly, hydrogen diffusion may increase a carrier concentration near the side portions of the active layer ACT, thereby forming or enhancing the contact regions CR1 and CR2.

An insulating interlayer 130 covering the gate electrode GE and the gate insulation layer 120 may be formed on the active layer ACT. The insulating interlayer 130 may be formed by the above-mentioned deposition process to include an inorganic insulating material such as silicon oxide (SiOx), silicon nitride (SiNx), silicon oxynitride (SiON), or other inorganic insulating materials. The insulating interlayer 130 may be formed in a single-layered structure or a multi-layered structure including different materials.

The contact electrodes CNT1 and CNT2, which may be in contact with or electrically connected to the active layer ACT, may be formed on the insulating interlayer 130.

The contact electrode may include a first contact electrode CNT1 that may be connected to or in contact with the first contact region CR1 of the active layer ACT, and a second contact electrode CNT2 that may be connected to or in contact with the second contact region CR2 of the active layer ACT. In some embodiments, the first contact electrode CNT1 and the second contact electrode CNT2 may serve as a source electrode and a drain electrode, respectively.

According to some embodiments, the insulating interlayer 130 may be partially etched to form contact holes. For example, contact holes exposing each of the first contact region CR1 and the second contact region CR2 may be formed through a photolithography and dry etching process. A metal layer may then be deposited to fill the contact holes on the insulating interlayer 130, and patterned to form the first contact electrode CNT1 and the second contact electrode CNT2. For example, a data signal may be provided from the data line to the active layer ACT via the first contact electrode CNT1.

The gate electrode GE and the contact electrodes CNT1 and CNT2 may include a metal such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd), scandium (Sc), an alloy thereof, or a metal nitride thereof. The gate electrode GE and the contact electrodes CNT1 and CNT2 may be formed by a deposition process such as a sputtering, evaporation, or metal-organic chemical vapor deposition (MOCVD) based on the material used.

The gate electrode GE and the contact electrodes CNT1 and CNT2 may be formed in a multi-layered stack structure (e.g., a Ti/Al/Ti layer). For example, the outer titanium (Ti) layers may serve as barrier or adhesion layers, and the central aluminum (Al) layer may provide low resistivity for signal transmission.

As described above, the first, second, and third transistor structures TR1, TR2, and TR3 may be formed as a thin film transistor (TFT)-array.

A first via insulation layer VIA1 covering the contact electrodes CNT1 and CNT2 may be formed on the insulating interlayer 130. The first via insulation layer VIA1 may be substantially provided as a planarization layer serving to reduce surface topography across the TFT-array and enable subsequent alignment.

The first via insulation layer VIA1 may be partially etched to form a first via hole exposing a top surface (or sometimes referred to as an upper surface) of one of the contact electrodes (e.g., the second contact electrode CNT2). An electrode layer may be deposited to fill the first via hole and cover a top surface of the first via insulation layer VIA1, and then may be partially etched (or patterned) to form a first via electrode VE1.

A second via insulation layer VIA2 covering the first via electrode VE1 may be formed on the first via insulation layer VIA1. The second via insulation layer VIA2 may be partially etched to form a second via hole exposing a top surface of the first via electrode VE1. An electrode layer may be deposited to fill the second via hole may be formed on a top surface of the second via insulation layer VIA2, and then may be partially etched to form the second via electrode VE2.

A third via insulation layer VIA3 covering the second via electrode VE2 may be formed on the second via insulation layer VIA2. The third via insulation layer VIA3 may be partially etched to form a third via hole exposing a top surface of the second via electrode VE2. An electrode layer (or an electrode material) may be deposited to fill the third via hole to form a third via electrode VE3. The third via electrode VE3 may also extend over the top surface of the third via insulation layer VIA3, providing an extended contact region for connection to a pixel electrode.

The first, second, and third via insulation layers VIA1, VIA2, and VIA3 may be formed as organic insulation layers. For example, the first, second, and third via insulation layers VIA1, VIA2, and VIA3 may include an organic polymer material such as polyimide, an epoxy resin, an acrylic resin, polyester, a siloxane resin, or a benzocyclobutene (BCB). These organic materials may provide enhanced flexibility, planarization, and stress relief for multilayer interconnect structures. For example, the first, second, and third via insulation layers VIA1, VIA2, and VIA3 may be formed by a coating process such as a spin coating process, slit coating process, or spray coating process.

The electrode layers for forming the via electrodes VE1, VE2, and VE3 may include a metal such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd), scandium (Sc), or an alloy thereof, or a metal nitride thereof. The electrode layers may be formed by a deposition process such as a sputtering process.

Each of the first, second, and third pixel electrodes PE1, PE2, and PE3 may be in contact with or electrically connected to the third via electrode VE3 on the third via insulation layer VIA3. Accordingly, the first, second, and third pixel electrodes PE1, PE2, and PE3 may be electrically connected to the contact electrode (e.g., the second contact electrode CNT2) of the first, second, and third transistor structures TR1, TR2, and TR3, respectively, through the via electrodes VE1, VE2, and VE3. In one aspect, the stacked interconnect architecture provides vertical routing from the transistor to the emission layer, and minimizing lateral area consumption.

FIG. 4 illustrates the via insulation layer as a triple-layered structure and the via electrode as a triple-layered structure, but the construction of the display device is not necessarily limited to the example illustrated in FIG. 4. For example, the via insulation layer/the via electrode may have a single-layered structure, a double-layered structure, or four or more via insulation layers/via electrodes.

The first, second, and third pixel electrodes PE1, PE2, and PE3 may be provided as the respective pixel electrode of the first light-emitting element EE1, the second light-emitting element EE2, and the third light-emitting element EE3, arranged in a first pixel area PX1, a second pixel area PX2, and a third pixel area PX3, respectively.

The pixel electrode PE may function as an anode of the corresponding light-emitting element EE. According to some embodiments, the pixel electrode PE may serve as a reflective electrode including a metal layer ML.

The pixel electrode PE may further include a transparent conductive oxide layer. According to some embodiments, the pixel electrode PE may have a multi-layered structure (e.g., a triple-layered structure) including a first transparent conductive oxide layer TCO1, the metal layer ML, and a second transparent conductive oxide layer TCO2 sequentially stacked on a top surface of the third via insulation layer VIA3.

Each of the first and second transparent conductive oxide layers TCO1 and TCO2 may include a transparent conductive oxide such as indium tin oxide (ITO), indium zinc oxide (IZO), zinc oxide (ZnO), and indium tin zinc oxide (ITZO). In some cases, these TCO layers may provide high optical transmittance and electrical conductivity while encapsulating the reflective metal layer.

The metal layer ML may include at least a metal such as silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), indium (In), tin (Sn) ,and zinc (Zn), or an alloy of two or more metals thereof. According to some embodiments, the metal layer ML may include silver (Ag) due to the high reflectivity. In some embodiments, the pixel electrode PE may have a triple-layered structure such as ITO/Ag/ITO.

A thickness of the metal layer ML may be greater than a thickness of each of the first transparent conductive oxide layer TCO1 and the second transparent conductive oxide layer TCO2. The first transparent conductive oxide layer TCO1 and the second transparent conductive oxide layer TCO2 may serve as a capping layer of the metal layer ML. Accordingly, damage, oxidation, or corrosion of the metal layer ML may be prevented or reduced in an etching process for forming the pixel electrode PE.

According to some embodiments of the present disclosure, a blocking layer BL may be disposed between the pixel electrodes PE. As illustrated in FIG. 3, the blocking layer BL may fill a space (or gap) between neighboring pixel electrodes PE in the display area DA. Top surfaces of the blocking layer BL and the pixel electrode PE may be substantially coplanar with each other to ensure planarization of the emission surface and uniform layer stacking in subsequent processes.

In some embodiments, the blocking layer BL may be formed as a continuous layer including openings or holes HL surrounding side surfaces of the pixel electrodes PE. These holes HL may represent emission apertures and physically separate adjacent pixel electrodes PE to minimize electrical or optical crosstalk.

The blocking layer BL may fill the space between the pixel electrodes PE. The blocking layer BL may be formed as an organic filling layer (e.g., an organic gap filling material). For example, the blocking layer BL may include a polyimide resin, a polyester resin, an epoxy resin, a siloxane resin, an acrylic resin, or other resin. In an embodiment, the blocking layer BL may include a polyimide resin.

The blocking layer BL may be formed between adjacent pixel electrodes PE and may be coplanar with the top surface of the pixel electrodes. In addition, the blocking layer BL may include hole regions HL that may surround the side surfaces of the pixel electrodes PE, providing lateral confinement and alignment tolerance during pixel electrode formation. This structure may ensure that the entire top surface of each pixel electrode PE remains exposed, and the side surfaces are embedded within the blocking material, resulting in a flat emission surface.

The pixel defining layer PDL exposing the top surface of each pixel electrode PE may be formed on the pixel electrode PE and the blocking layer BL. The pixel defining layer PDL may be formed to at least partially expose the top surface of the pixel electrode PE to form a pixel area. The pixel defining layer PDL may cover a peripheral portion of the pixel electrode PE. For example, the pixel defining layer PDL may form a pixel opening through which organic/inorganic light-emitting materials can be deposited. The pixel defining layer PDL may further cover the peripheral edge regions (or side surfaces) of each pixel electrode PE to serve as a boundary for material patterning.

The pixel defining layer PDL may include, for example, an organic material such as a polysiloxane resin, a polyimide resin, an acrylic resin, or other organic resins. The pixel defining layer PDL may include a colorant such as a black pigment or dye dispersed in the resin material.

As illustrated in FIG. 3, the pixel defining layer PDL may include an opening OP partially exposing the top surface of each of the first pixel electrode PE1, the second pixel electrode PE2, and the third pixel electrode PE3. The first pixel area PX1, the second pixel area PX2, and the third pixel area PX3 may be substantially formed by the respective exposed portions (e.g., openings OP) of the top surfaces of the first pixel electrode PE1, the second pixel electrode PE2, and the third pixel electrode PE3, respectively.

As described above, the blocking layer BL may include the hole HL that laterally surrounds the side surfaces of each of the pixel electrodes PE, and the top surface of the pixel electrode PE may be fully exposed through the corresponding hole HL.

In an embodiment, in a plan view of FIG. 3, an area of the hole HL may be greater than an area of the opening OP. The opening OP and the hole HL may partially or completely overlap each other in each pixel area, and the opening OP may be fully enclosed within the boundary of the hole HL.

In some embodiments, the pixel defining layer PDL may fully cover the blocking layer BL. For example, the pixel defining layer PDL may be in contact with an entire top surface of the blocking layer BL, providing planar support and boundary isolation between adjacent pixels.

As illustrated in FIG. 3, the first pixel area PX1 (corresponding to the first pixel electrode PE1), the second pixel area PX2 (corresponding to the second pixel electrode PE2), and the third pixel area PX3 (corresponding to the first pixel electrode PE3) may be disposed adjacent to one another in a rectangular pentile pattern. In one aspect, this configuration enables high-resolution subpixel placement and minimizing color crosstalk. However, examples are not necessarily limited thereto.

The first pixel area PX1 may have a relatively elongated rectangular shape longer than each of the second pixel area PX2 and the third pixel area PX3. The second pixel area PX2 and the third pixel area PX3 may be disposed adjacent to a long side of the first pixel area PX1, and the second pixel area PX2 and the third pixel area PX3 may be adjacent to each other in the second direction or a long side direction of the first pixel area PX1.

A pixel group may include the above-described configuration of the first pixel area PX1, the second pixel area PX2, and the third pixel area PX3. A plurality of the pixel groups may be repeatedly arranged along the first direction and the second direction, thereby forming a matrix-type subpixel layout across the display area DA.

In some embodiments, the first pixel area PX1, the second pixel area PX2, and the third pixel area PX3 may correspond to a blue pixel area, a green pixel area, and a red pixel area, respectively.

The above-described pixel arrangement or configuration of FIG. 3 is provided as an example, and the pixel arrangement or configuration of the display device is not necessarily limited to the example illustrated in FIG. 3.

The light-emitting portion EL may be formed on the top surface of the pixel electrode PE and on a portion of the surface of the pixel defining layer PDL. The light-emitting portion EL may include an organic emission layer that may be separately patterned for each of the red pixel area, the green pixel area, and the blue pixel area to emit light having different color in each pixel.

In an embodiment, the light-emitting portion EL may continuously and commonly extend across a plurality of pixels. For example, the light-emitting portion EL may include a white emitting layer or a blue emitting layer. In an embodiment, the light-emitting portion EL may include multiple stacked emission layers forming a tandem structure capable of emitting different colors from vertically integrated sublayers.

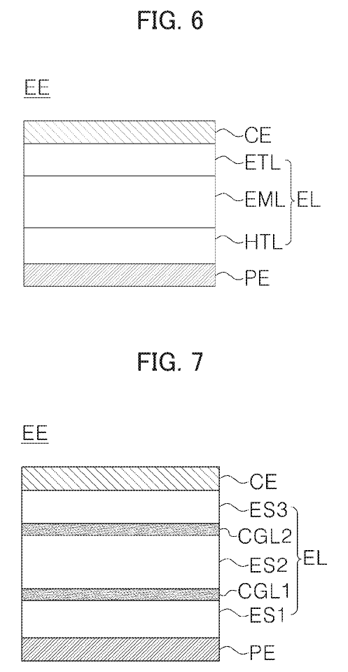

The light-emitting element EE including the light-emitting portion EL is described in detail with reference to FIGS. 6 and 7.

A counter electrode CE may be disposed on the light-emitting portion EL. The counter electrode CE may be a common electrode that may be continuously and uniformly formed over a plurality of the pixel regions across the display area DA.

The counter electrode CE may serve as an electron injection electrode or a cathode. The counter electrode CE may include a metal, an alloy, an electrically conductive compound, or the like having a low work function.

For example, the counter electrode CE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or other metal elements or alloys.

The counter electrode CE may be formed as a transmissive electrode, a translucent electrode, or a reflective electrode based on the target emission direction (e.g., top-emission or bottom-emission). The counter electrode CE may have a single-layered structure or a multi-layered structure. In some cases, the counter electrode CE may include a transparent conductive oxide layer and/or a metal layer.

The counter electrode CE may be formed by a deposition process such as a sputtering process using a target including the above-described conductive material.

The light-emitting element EE may be defined by the pixel electrode PE, the light-emitting portion EL, and the counter electrode CE as described above. The light- emitting element EE may be implemented as an organic light-emitting diode (OLED) element.

The first light-emitting element EE1 may be formed by the first pixel electrode PE1, the light-emitting portion EL, and the counter electrode CE. The second light-emitting element EE2 may be formed by the second pixel electrode PE2, the light-emitting portion EL, and the counter electrode CE. The third light-emitting element EE3 may be formed by the third pixel electrode PE3, the light-emitting portion EL, and the counter electrode CE.

An encapsulation layer TFE may be formed on the counter electrode CE. The encapsulation layer TFE may be disposed on the pixel defining layer PDL and the light-emitting elements EE to protect the light-emitting elements EE from moisture or oxygen. The encapsulation layer TFE may extend over the pixel defining layer PDL and cover the light-emitting elements EE to shield the organic layers from environmental contaminants such as moisture and oxygen, thereby improving operational stability and device lifetime. In some cases, the encapsulation layer TFE may have a thin-film encapsulation structure including one or more inorganic and/or organic sublayers

The encapsulation layer TFE may include an inorganic layer including silicon nitride (SiNx), silicon oxide (SiOx), indium tin oxide, indium zinc oxide, or any combination thereof. The encapsulation layer TFE may include an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof. In some cases, the encapsulation layer TFE may include a combination of the inorganic and organic layers.

The encapsulation layer TFE may be formed as a single-layered structure or a multi-layered structure. In some embodiments, the encapsulation layer TFE may have a sequential stacked structure including a first inorganic layer, an organic layer, and a second inorganic layer. In one aspect, the encapsulation layer TFE may provide enhanced barrier characteristics through alternating moisture and oxygen resistance and mechanical flexibility.

In some embodiments, a color control layer overlapping the light-emitting portion EL may be disposed on the encapsulation layer TFE. The color control layer may include a color conversion layer including quantum dots and/or a color filter.

In some embodiments, a sensor layer such as a touch sensor layer and/or an optical functional layer such as a polarizing plate, an anti-reflection layer, an antistatic layer, or other optical functional layers, may be disposed on the encapsulation layer TFE. These additional layers may provide interactive input functionality and enhance the optical and environmental performance of the display device.

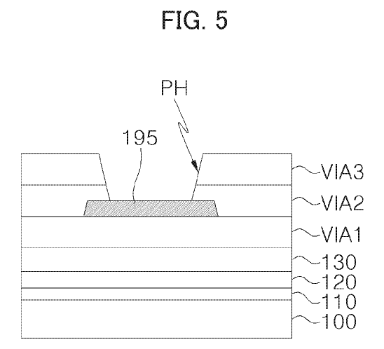

FIG. 5 is a schematic cross-sectional view illustrating a peripheral area or a pad area of a display device according to some embodiments.

Referring to FIG. 5, as described with reference to FIG. 1, the peripheral circuit PC and the pads 195 may be arranged in the non-display area NDA of the base substrate 100. The pads 195 may function as an external electrical connection terminal and may serve as a bonding interface to a separate component such as flexible printed circuit board (FPCB) or a chip-on-film (COF) structure.

As illustrated in FIG. 5, the pads 195 may be disposed on the first via insulation layer VIA1. The second and third via insulation layers VIA2 and VIA3 may partially cover the top surface of the pads 195. A pad hole PH may be formed through the second and third via insulation layers VIA2 and VIA3 to expose a portion or the entirety of the top surface of the pads 195. The pad hole PH may enable electrical connection to external circuits via various bonding methods.

In some embodiments, the first, second, and third via insulation layers VIA1, VIA2, and VIA3 may be selectively or completely removed from the non-display area NDA or the pad area. For example, the pads 195 may be disposed on the insulating interlayer 130.

The blocking layer BL might not cover the peripheral circuit PC and the pads 195. In some embodiments, the blocking layer BL may be substantially removed from the non-display area NDA and may be disposed only on the display area DA.

FIGS. 6 and 7 are schematic cross-sectional views illustrating a light-emitting element according to some embodiments.

Referring to FIG. 6, the light-emitting element EE may include the pixel electrode PE, the counter electrode CE, and the light-emitting portion EL disposed between the pixel electrode PE and the counter electrode CE as described above.

The light-emitting portion EL may include a hole transport layer HTL, an emission layer EML and an electron transport layer ETL. According to some embodiments, the hole transport layer HTL, the emission layer EML, the electron transport layer ETL and the counter electrode CE may be sequentially stacked in the third direction from the top surface of the pixel electrode PE.

The emission layer EML may include an organic light-emitting material having red, green, or blue emission characteristics. For example, the emission layer EML may include a fluorescent host and/or a host for a phosphorescent device, and may further include a fluorescent dopant, a phosphorescent dopant, and/or a thermally activated delayed fluorescence (TADF) dopant.

According to some embodiments, the emission layer EML may include a first emission layer disposed in the first pixel area PX1, a second emission layer disposed in the second pixel area PX2, and a third emission layer disposed in the third pixel area PX3. For example, the first emission layer, the second emission layer and the third emission layer may be a blue emission layer, a green emission layer, and a red emission layer, respectively, and may be individually patterned using inkjet printing, mask deposition, or other patterning methods.

For example, the hole transport layer HTL may include a hole transport material such as m-MTDATA (4,4',4"-[tris(3-methylphenyl)phenylamino] triphenylamine), TDATA (4,4'4"-tris(N,N-diphenylamino)triphenylamine), 2-TNATA (4,4',4"-tris[N(2-naphthyl)-N-phenylamino]-triphenylamine), NPB (N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), or other materials.

For example, the electron transport layer ETL may include an electron transport material such as Alq₃ (tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), or other materials.

In some embodiments, the hole transport layer HTL and the electron transport layer ETL may be formed as a common continuous layer that extend across all the first, second, and third pixel areas PX1, PX2, and PX3, thus simplifies the fabrication process and improves interlayer interface stability.

In some embodiments, a hole injection layer may be further disposed between the pixel electrode PE and the hole transport layer HTL. An electron injection layer may be further disposed between the counter electrode CE and the electron transport layer ETL.

The layers included in the light-emitting portion EL may be formed by a thermal deposition, an evaporation deposition, a vacuum deposition, a spin coating, an inkjet printing, a laser printing, a casting, a laser thermal transfer, or other deposition methods.

Referring to FIG. 7, the light-emitting portion EL may include a plurality of the light-emitting structures ES1, ES2, and ES3. Each of the light-emitting structures ES1, ES2 and ES3 may include a hole transport layer, an emission layer, and an electron transport layer. According to some embodiments, the light-emitting element EE of FIG. 7 may be a light-emitting device having a tandem structure that generates a white light or a blue light. For example, the light-emitting element EE may be implemented as a tandem OLED device designed to achieve either white light emission (via multi-wavelength stacking) or enhanced blue emission (via repeated blue sub-structures), based on the selected materials for each emission layer EML.

Charge generation layers CGL1 and CGL2 may be disposed between the neighboring light-emitting structures. The charge generation layers CGL1 and CGL2 may include a p-type charge generation layer and/or an n-type charge generation material, forming a bipolar interface that facilitates carrier recombination and charge transfer between the first light-emitting structure ES1 and the second light-emitting structure ES2. For example, the first charge generation layer CGL1 may be formed between the first light-emitting structure ES1 and the second light-emitting structure ES2, and a second charge generation layer CGL2 may be formed between the second light-emitting structure ES2 and the third light-emitting structure ES3.

According to some embodiments, the first light-emitting structure ES1, the first charge generation layer CGL1, the second light-emitting structure ES2, the second charge generation layer CGL2, the third light-emitting structure ES3, and the counter electrode CE may be sequentially stacked from the top surface of the pixel electrode PE.

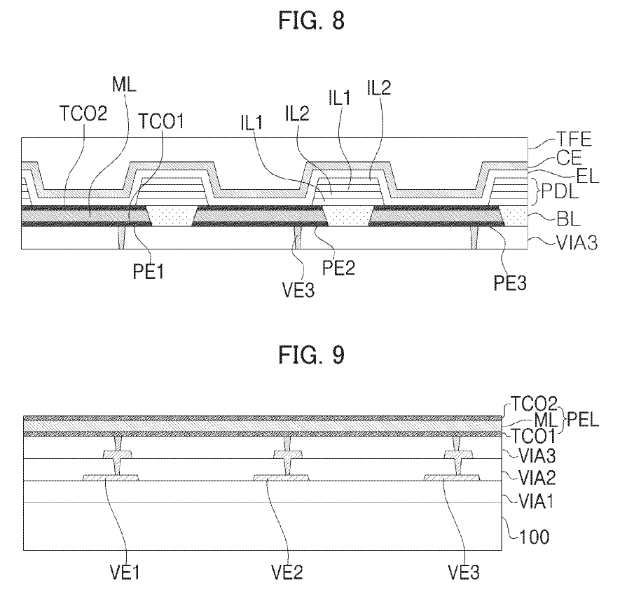

FIG. 8 is a partially enlarged cross-sectional view of a display device according to some embodiments. Detailed descriptions on elements and structures substantially the same as or similar to those described with reference to FIGS. 3 to 7 might not be described. For convenience of descriptions, illustration of detailed structures under the third via insulation layer VIA3 is omitted in FIG. 8.

Referring to FIG. 8, the pixel defining layer may include a stack of inorganic insulation layers. According to some embodiments, the pixel defining layer PDL may include a first inorganic insulation layer IL1 and a second inorganic insulation layer IL2.

The first inorganic insulation layer IL1 and the second inorganic insulation layer IL2 may be alternately and repeatedly stacked from the top surface of the blocking layer BL in the pixel defining layer PDL. The first inorganic insulation layer IL1 and the second inorganic insulation layer IL2 may have different refractive indices. The first inorganic insulation layer IL1 and the second inorganic insulation layer IL2 may enable the pixel defining layer PDL to function as an optical interference stack, achieving enhanced light blocking performance (e.g., via destructive interference or index contrast). Accordingly, light-shielding properties may be substantially implemented from the pixel defining layer PDL.

In some embodiments, the first inorganic insulation layer IL1 may include silicon oxide (SiOx), and the second inorganic insulation layer IL2 may include silicon nitride (SiNy). This combination may optimize the optical reflectance suppression and etch selectivity during fabrication. The inorganic nature of the pixel defining layer PDL may further provide mechanical robustness and long-term thermal stability compared to other pixel defining layers.

FIGS. 9 to 15 are schematic cross-sectional views illustrating a method of manufacturing a display device according to some embodiments. For convenience of descriptions, detailed illustration of the TFT-array described with reference to FIG. 4 between the first via insulation layer VIA1 and the base substrate 100 might not be described in FIGS. 9 to 15.

Referring to FIG. 9, as described with reference to FIG. 4, the TFT-array including first, second, and third transistor structures TR1, TR2, and TR3 may be formed on the base substrate 100.

A first via insulation layer VIA1 covering the first, second, and third transistor structures TR1, TR2, and TR3 may be formed, and the first via electrode VE1 may be formed to be connected to each of the contact electrodes included in the first, second, and third transistor structures TR1, TR2, and TR3 through the first via insulation layer VIA1.

Thereafter, as described with reference to FIG. 3, the second via insulation layer VIA2, the second via electrode VE2, the third via insulation layer VIA3, and the third via electrode VE3 may be sequentially formed.

A pixel electrode layer PEL may be formed on the third via insulation layer VIA3 and in electrical contact with the third via electrode VE3.

According to some embodiments, the pixel electrode layer PEL may be formed by sequentially depositing the first transparent conductive oxide layer TCO1, the metal layer ML, and the second transparent conductive oxide layer TCO2 on the third via insulation layer VIA3 and the third via electrode VE3.

As described above, in some embodiments, the first transparent conductive oxide layer TCO1, the metal layer ML, and the second transparent conductive oxide layer TCO2 may include indium tin oxide (ITO), silver (Ag), and indium tin oxide (ITO), respectively. For example, the first transparent conductive oxide layer TCO1, the metal layer ML, and the second transparent conductive oxide layer TCO2 may be formed by a deposition process such as a sputtering process.

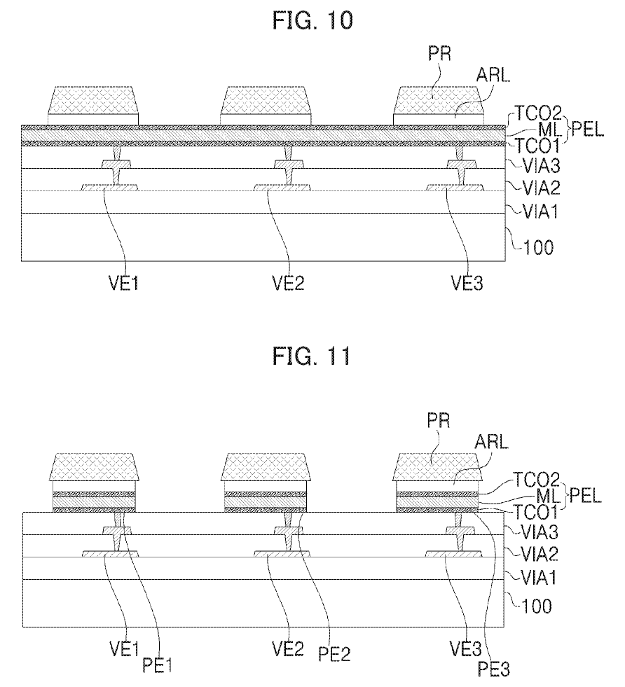

Referring to FIG. 10, a photoresist pattern PR may be formed on the pixel electrode layer PEL to form the pixel electrode areas.

For example, a photoresist layer may be formed on the pixel electrode layer PEL, and may be partially removed by exposure and development processes to form the photoresist pattern PR. The photoresist pattern PR may be formed on regions of the pixel electrode layer PEL corresponding to the first, second, and third pixel electrodes PE1, PE2, and PE3.

In some embodiments, an anti-reflection layer ARL may be further formed between the photoresist pattern PR and the pixel electrode layer PEL. The anti-reflection layer ARL may be formed using an organic polymer-based bottom anti-reflection coating (BARC) composition. The anti-reflection layer ARL may be included to prevent a resolution decrease due to a diffuse reflection during the exposure process.

Referring to FIG. 11, the pixel electrode layer PEL may be partially etched using the photoresist pattern PR. Accordingly, the first pixel electrode PE1, the second pixel electrode PE2, and the third pixel electrode PE3 may be formed from the pixel electrode layer PEL. Each of the first pixel electrode PE1, the second pixel electrode PE2, and the third pixel electrode PE3 may include the first transparent conductive oxide layer TCO1, the metal layer ML, and the second transparent conductive oxide layer TCO2.

According to some embodiments, the etching of the pixel electrode layer PEL may be performed using a wet etching process. The metal layer ML may include silver (Ag) due to the superior reflectivity and electrical conductivity. If a dry etching process is performed, silver residues may be generated, potentially leading to contamination or degraded device performance.

Thus, the silver residues may be prevented by using wet etching. Additionally, the wet etching process combined with the presence of the anti-reflection layer ARL may prevent an excessive skew or undercut phenomenon of the pixel electrode PE.

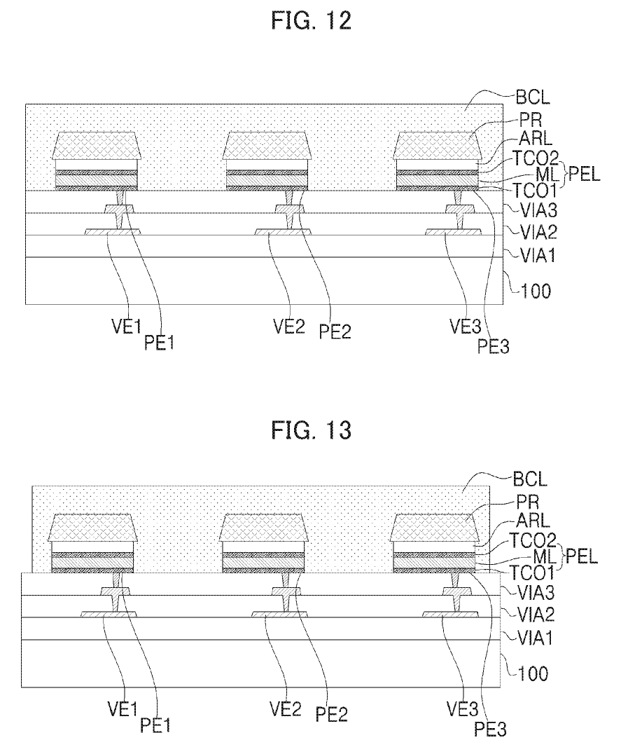

Referring to FIG. 12, a blocking coating layer BCL covering the pixel electrodes PE1, PE2, and PE3, and the photoresist patterns PR may be formed on the third via insulation layer VIA3. The blocking coating layer BCL may serve as an organic planarization and isolation layer, filling gaps between pixel electrodes and providing a smooth surface for subsequent layer formation.

According to some embodiments, the blocking coating layer BCL may be formed by a coating process such as spin coating or a slit coating using an organic polymer material including a polyimide resin, a polyester resin, an epoxy resin, a siloxane resin, an acrylic resin, or other suitable polymers.

In some embodiments, the blocking coating layer BCL may be formed using the polyimide resin. In an embodiment, the blocking coating layer BCL may be formed using a photosensitive organic polymer such as a photosensitive polyimide (PSPI) resin.

Referring to FIG. 13, a side portion or a peripheral portion of the blocking coating layer BCL may be selectively removed. According to some embodiments, a portion of the blocking coating layer BCL covering the peripheral circuit PC and/or the pads 195 may be removed through a photo-lithography process. In some embodiments, a portion of the blocking coating layer BCL formed on the non-display area NDA may be substantially removed.

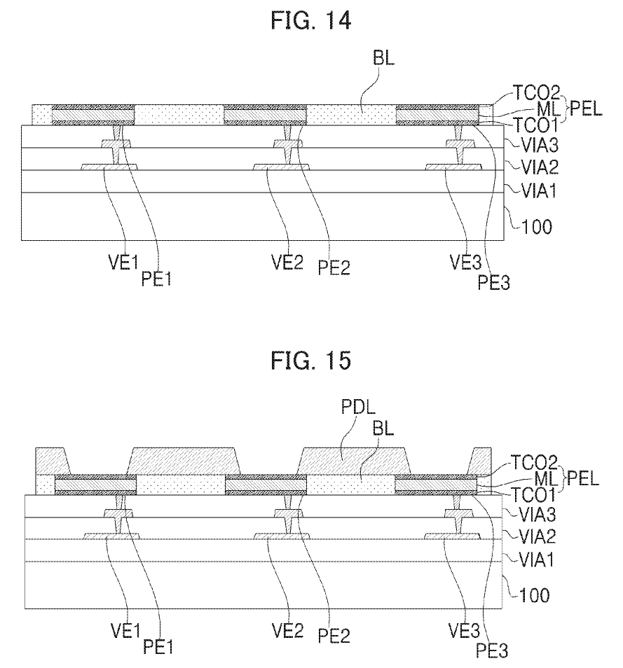

Referring to FIG. 14, the photoresist pattern PR may be removed simultaneously with the removal of an upper portion of the blocking coating layer BCL to form the blocking layer BL between the pixel electrodes PE.

In some embodiments, upper portions of the photoresist pattern PR and the blocking coating layer BCL may be removed together through an ashing process. The ashing process may be a dry etch process using an oxygen plasma.

According to some embodiments, the blocking layer BL may serve as a sidewall protective layer of the pixel electrode PE, thereby preventing oxidation/damage of the metal layer ML due to the oxygen plasma. For example, silver (Ag) included in the metal layer ML may be oxidized before being etched, and may be easily transformed into silver oxide (AgO) upon exposure to the oxygen plasma during etching or ashing.

However, the blocking layer BL may be disposed between the pixel electrodes PE1, PE2, and PE3 to shield the side surfaces of the pixel electrodes PE1, PE2, and PE3. Accordingly, damages to the side surfaces of the metal layer ML due to the ashing process may be prevented, and target hole injection properties and electrical conductivity of the pixel electrode PE may be preserved.

The ashing process may be performed until the top surface of the pixel electrode PE or a top surface of the second transparent conductive oxide layer TCO2 is exposed. The second transparent conductive oxide layer TCO2 may serve as an ashing stopper layer due to the resistance to oxygen plasma etching. Accordingly, the top surface of the blocking layer BL and the top surface of the second transparent conductive oxide layer TCO2 may be substantially coplanar.

The anti-reflection layer ARL may also be removed by the ashing process. In an embodiment, the ashing process may be performed until the anti-reflection layer ARL is removed.

In some embodiments, upper portions of the photoresist pattern PR and the blocking coating layer BCL may be removed together by a chemical mechanical polishing (CMP) process. The CMP process may be performed until the top surface of the pixel electrode PE or the upper surface of the second transparent conductive oxide layer TCO2 is exposed. Similar to the ashing process, the second transparent conductive oxide layer TCO2 may function as a polishing stopper layer. Accordingly, the top surface of the blocking layer BL may be located at substantially the same plane as the top surface of the second transparent conductive oxide layer TCO2.

The anti-reflection layer ARL may also be removed by the polishing process. In an embodiment, the polishing process may be performed until the anti-reflection layer ARL is removed.

Referring to FIG. 15, as described with reference to FIG. 4, the pixel defining layer PDL may be formed on the top surfaces of the pixel electrodes PE1, PE2, and PE3 and on the blocking layer BL. The first pixel area PX1, the second pixel area PX2, and the third pixel area PX3 may be formed and separated by the pixel defining layer PDL.

In some embodiments, as described with reference to FIG. 8, the pixel defining layer PDL may include an inorganic layer stack formed by alternately and repeatedly depositing the first inorganic insulation layer IL1 and the second inorganic insulation layer IL2. The inorganic layer stack may be partially etched to form the pixel defining layer PDL.

According to some embodiments, the blocking layer BL may fill a space between adjacent pixel electrodes PE. Accordingly, the top surface of the inorganic layer stack or the pixel defining layer PDL may be substantially flat, and a height of the pixel defining layer PDL may be preserved.

Hereinafter, as described with reference to FIG. 4, the light-emitting portion EL, the counter electrode CE, and the encapsulation layer TFE may be sequentially formed on the pixel electrodes PE and the pixel defining layer PDL.

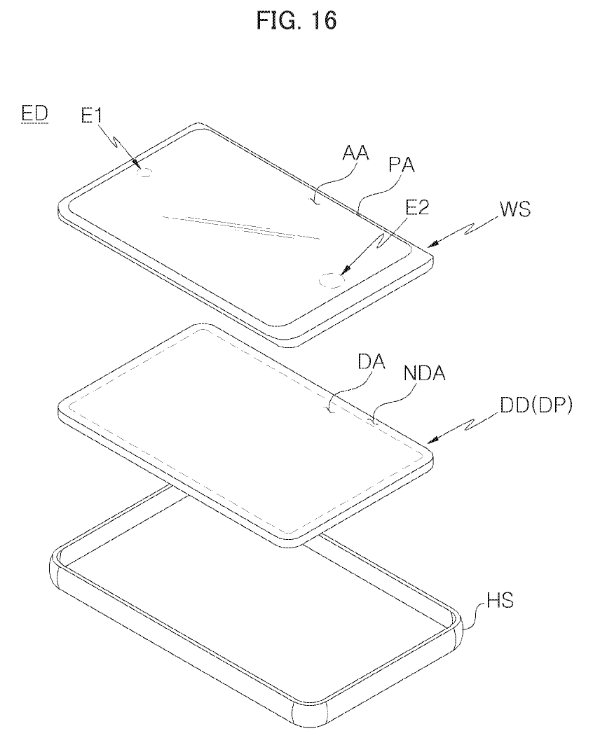

FIG. 16 is an exploded perspective view of a display device according to some embodiments.

According to some embodiments, an electronic device ED may be implemented in the form of a mobile phone (smart phone), a tablet computer, a desktop computer, or other portable or stationary electronic devices that include the above-described display device.

Referring to FIG. 16, the electronic device ED may include a window structure WS, a display device DD, and a housing HS. The display device DD may include a display panel DP including the transistor structures and the light-emitting element EE as described above. The housing HS, the display device DD, and the window structure WS may be sequentially stacked in the third direction.

The window structure WS may provide an external display surface recognized by a user of a display, and may include a transparent material film. For example, the window structure WS may include glass (e.g., ultra-thin glass (UTG)), a hard coating film, a plastic film, or other suitable transparent materials.

An outer surface of the window structure WS may include an active area AA and a peripheral area PA. The active area AA may provide a surface from which an image generated by the display device DD is displayed and to which user input, such as touch or command may be applied. The peripheral area PA may substantially correspond to a bezel area of the display device.

As described with reference to FIG. 1. the display device DD and the display panel DP may have a display area DA and a non-display area NDA. The display area DA of the display panel DP may correspond to or overlap the active area AA of the window structure WS. The non-display area NDA of the display panel DP may correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, for example, in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The housing HS may serve as a frame or a housing for the display device DD or the electronic device ED. A cover panel may be disposed between the housing HS and the display panel DP. The housing HS or the cover panel may include a support plate (e.g., an SUS plate) that supports the display panel DP, and/or the printed circuit board 200 (see FIG. 1). The housing HS or the cover panel may include an elastic body for absorbing shock of the display device DD.

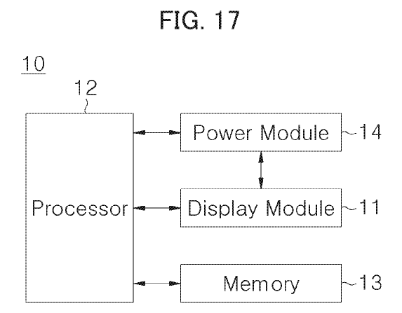

FIG. 17 is a block diagram of an electronic device according to an embodiment.

Referring to FIG. 17, an electronic device 10 may include a display module 11, a processor 12, a memory 13 and a power module 14.

The processor 12 may include one or more of a central processing unit (CPU), an application processor (AP), a graphics processing unit (GPU), a communication processor (CP), an image signal processor (ISP), and/or a controller. In some cases, the processor 12 may control the overall operation of the electronic device 10, including driving the display module 11 based on image and data signals stored in memory 13. The power module 14 may supply and control electrical power provided to each of the functional components.

Data for operating the processor 12 or the display module 11 may be stored in the memory 13. When the processor 12 executes an application stored in the memory 13, the processor 12 may transmit image data signal and/or an input control signal to the display module 11, and the display module 11 may process the received signal and output image information through a display screen.

The power module 14 may include a power supply module such as a power adapter or a battery device, and a power conversion module that converts a power to operate the electronic device 10.

At least one of components of the electronic device 10 as described above may be included in the display device. Additionally, some of individual modules functionally included in one module may be included in the display device, and other modules may be included in a device other than the display device. For example, the display module 11 may include the display device, and the processor 12, the memory 13, and the power module 14 may be provided in another device from the display device.

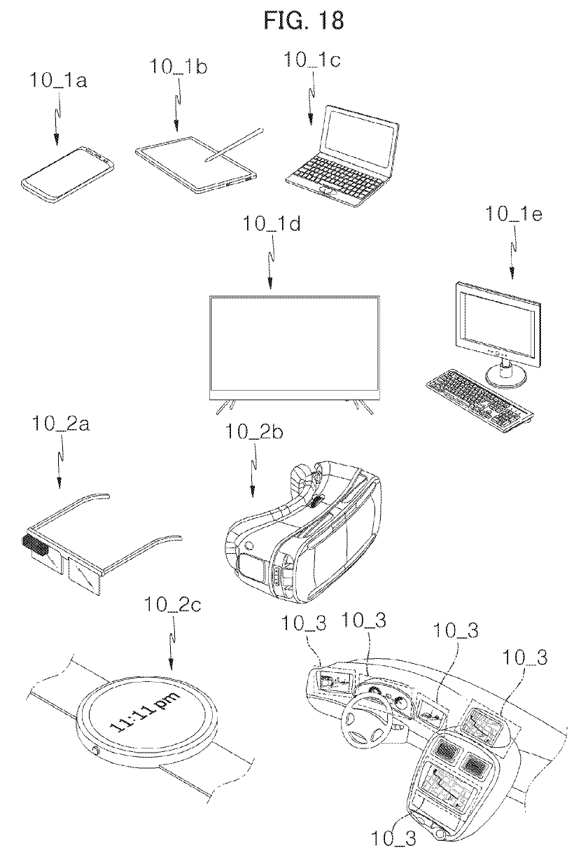

FIG. 18 is a schematic diagram of electronic devices according to some embodiments.

Referring to FIG. 18, non-limiting examples of various electronic devices to which the display device is applied include an electronic device for displaying an image such as a smartphone 10_1a, a tablet computer 10_1b, a laptop computer 10_1c, a television (TV) 10_1d, a desk monitor 10_1e. The electronic device may be implemented as a wearable electronic device including a display module such as smart glasses 10_2a, a head mounted display 10_2b, a smart watch 10_2c. The electronic device may be implemented as a vehicle electronic device 10_3 including a display module such as a center information display (CID) disposed at a vehicle instrument panel, a center fascia, a dashboard, a head-up display, or a room mirror display. The electronic device may include a virtual reality glasses or an augmented reality glasses.

In the detailed description, those skilled in the art will appreciate that many variations and modifications can be made to the preferred embodiments without substantially departing from the technical scope and principles of the present inventive concept. Therefore, the disclosed preferred embodiments of the invention are used in a generic and descriptive sense.

What is claimed is:

1. A display device, comprising:
a base substrate;
pixel electrodes spaced apart from each other and disposed on the base substrate;
a blocking layer disposed between the pixel electrodes, wherein an upper surface of the blocking layer is coplanar with upper surfaces of the pixel electrodes;
a light-emitting portion disposed on the pixel electrodes; and
a counter electrode disposed on the light-emitting portion.

2. The display device of claim 1, wherein:
the blocking layer surrounds side surfaces of the pixel electrodes.

3. The display device of claim 2, further comprising:
a pixel defining layer covering the upper surface of the blocking layer to define pixel areas on the pixel electrodes.

4. The display device of claim 3, wherein:
the pixel defining layer completely covers the upper surface of the blocking layer and at least a portion of the upper surfaces of the pixel electrodes.

5. The display device of claim 3, wherein:
the blocking layer includes a hole into which each of the pixel electrodes is inserted,
the pixel defining layer includes an opening overlapping the hole and exposing an upper surface of each of the pixel electrodes, and
an area of the hole is larger than an area of the opening in a plan view.

6. The display device of claim 1, wherein:
the blocking layer includes an organic polymer material.

7. The display device of claim 1, wherein:
the pixel electrodes include a first transparent conductive oxide layer, a metal layer, and a second transparent conductive oxide layer that are sequentially stacked.

8. The display device of claim 7, wherein:
the metal layer includes silver (Ag).

9. The display device of claim 1, further comprising:
transistor structures disposed on the base substrate and electrically connected to each of the pixel electrodes; and
a peripheral circuit and pads electrically connected to the transistor structures,
wherein the base substrate includes a display area including the transistor structures, and a non-display area surrounding the display area, and
wherein the non-display area includes the peripheral circuit and the pads.

10. The display device of claim 9, wherein:
the blocking layer exposes the peripheral circuit and/or the pads.

11. The display device of claim 10, wherein:
the blocking layer is disposed only on the display area.

12. A method of manufacturing a display device, the method comprising:
forming a via insulation layer on a base substrate;
forming a pixel electrode layer on the via insulation layer;
forming photoresist patterns on the pixel electrode layer;
etching the pixel electrode layer using the photoresist patterns to form pixel electrodes;
forming a blocking coating layer covering the photoresist patterns and the pixel electrodes;
removing upper portions of the blocking coating layer and the photoresist patterns to form a blocking layer between the pixel electrodes;
forming a light-emitting portion on the pixel electrodes; and
forming a counter electrode on the light-emitting portion.

13. The method of claim 12, wherein removing the upper portions of the blocking coating layer and the photoresist patterns includes:
performing an ashing process.

14. The method of claim 13, wherein forming the pixel electrode layer comprises:
sequentially forming a first transparent conductive oxide layer, a metal layer including silver (Ag), and a second transparent conductive oxide layer on the via insulation layer,
wherein the second transparent conductive oxide layer is an ashing stopper layer during the ashing process.

15. The method of claim 12, wherein removing the upper portions of the blocking coating layer and the photoresist patterns includes:
performing a chemical mechanical polishing (CMP) process.

16. The method of claim 15, wherein forming the pixel electrode layer includes:
sequentially forming a first transparent conductive oxide layer, a metal layer including silver (Ag), and a second transparent conductive oxide layer on the via insulation layer,
wherein the second transparent conductive oxide layer is a polishing stopper layer during the CMP process.

17. The method of claim 12, further comprising:
removing a side portion of the blocking coating layer.

18. The method of claim 17, wherein:
the blocking coating layer is formed using a photosensitive organic polymer.

19. An electronic device, comprising:
a display device;
a memory having a stored application for operating the electronic device including the display device; and
a processor configured to execute the application stored in the memory,
wherein the display device comprises:
a base substrate;
pixel electrodes spaced apart from each other and disposed on the base substrate;
a blocking layer disposed between the pixel electrodes, wherein an upper surface of the blocking layer is coplanar with upper surfaces of the pixel electrodes;
a light-emitting portion disposed on the pixel electrodes; and
a counter electrode disposed on the light-emitting portion.

20. The electronic device of claim 19, wherein:
the electronic device includes virtual reality or augmented reality glasses, a smartphone, a tablet PC, a laptop, a TV, a desk monitor, smart glasses, a head-mounted display, a smart watch, or a vehicle display.
